(19) United States
(12) Patent Application Publication
(10) Pub. No.: US 2012/0055700 A1
(43) Pub. Date: Mar. 8, 2012

(54) DOUBLE-SIDED PRESSURE-SENSITIVE ADHESIVE TAPE FOR FIXING FLEXIBLE PRINTED CIRCUIT BOARD AND FLEXIBLE PRINTED CIRCUIT BOARD WITH THE SAME

(75) Inventors: Hakaru Horiguchi, Ibaraki-shi (JP); Noritsugu Daigaku, Ibaraki-shi (JP); Takahiro Nonaka, Ibaraki-shi (JP); Rie Kuwahara, Ibaraki-shi (JP)

(73) Assignee: NITTO DENKO CORPORATION, Ibaraki-shi (JP)

(21) Appl. No.: 13/223,509

(22) Filed: Sep. 1, 2011

(30) Foreign Application Priority Data
Sep. 8, 2010 (JP) 2010-201073

(51) Int. Cl. H05K 1/02; B32B 7/10

(52) U.S. Cl. 174/254; 428/354; 428/220

(57) ABSTRACT

Provided is a double-sided pressure-sensitive adhesive tape for fixing a flexible printed circuit board superior in adhesive power after bonding under low pressure and also in repelling resistance after processing in high-temperature steps. The double sided pressure-sensitive adhesive tape for fixing a flexible printed circuit board according to the present invention has a 180° peel adhesion, as determined by bonding the adhesive tape onto a stainless steel plate under pressure by one reciprocation of a 10-g roller, leaving it still for 5 minutes and measuring it at a tensile speed of 300 mm/minute, of 6.5 N/20 mm or more and a terminal separation distance after reflow of 2.5 mm or less.

### TECHNICAL FIELD

The present invention relates to a double-sided pressure-sensitive adhesive tape for use in the application of fixing a flexible printed circuit board and a flexible printed circuit board carrying the double-sided pressure-sensitive adhesive tape.

### BACKGROUND ART

Wiring circuit boards have been used in electronic devices, and flexible printed circuit boards (hereinafter, referred to simply as “FPCs”) have been used widely as such wiring circuit boards. FPCs are normally used as they are in the state fixed for example to the casing of an electronic device or the reinforcing plate, and a double-sided adhesive sheet (double-sided pressure-sensitive adhesive sheet) is used for adhesion to the casing or the reinforcing plate.

FPCs are often exposed to high-temperature steps such as reflow step (reflow soldering step). The FPCs after the high-temperature steps had a problem of separation (peeling) of the double-sided pressure-sensitive adhesive tape from the adherend, when they are bonded in the state where repulsive force is generated, for example when they are bonded to the bent or uneven region of the adherend.

To overcome the problem, known is a double-sided pressure-sensitive adhesive tape in the configuration having an adhesive composition for preparation of the adhesive layer and a chain transfer material added thereto (see Patent Document 1). Such a double-sided pressure-sensitive adhesive tape is resistant to increase of the gel fraction of the adhesive layer after processing in high-temperature steps and thus to entire or terminal separation from the adherend, even if the adhesive tape is affixed to an adherend in the state where repulsive force is generated after processing in high-temperature steps. The property of the adhesive tape resistant to entire or terminal separation when bonded to an adherend in the state where repulsive force is generated will be referred to as “repelling resistance”.

A double-sided pressure-sensitive adhesive tape may be bonded to an FPC carrying components such as electronic parts mounted thereon, depending on the production process of electronic devices. In such a case, for prevention of breakdown of the electronic parts and others mounted on the FPC, it is needed to bond and fix the double-sided pressure-sensitive adhesive tape to a FPC under smaller force (pressure).

However, the double-sided pressure-sensitive adhesive tape described in Patent Document 1, which has an adhesive layer higher in elastic force at normal temperature because of addition of the chain migration substance, had a problem that the adhesive layer is less adhesive when bonded under smaller force (pressure) and the double-sided pressure-sensitive adhesive tape cannot be bonded tightly to the FPC. Under the circumstances above, there currently exists a need for a double-sided pressure-sensitive adhesive tape superior in the repelling resistance after processing in high-temperature steps and also in adhesive power after it is bonded under smaller force (hereinafter, referred to as “adhesive power after bonding under low pressure”).

### CITATION LIST

### Patent Literature

Patent Document 1: Japanese Unexamined Patent Publication No. 2007-302868

### SUMMARY OF INVENTION

### Technical Problem

Accordingly, an object of the present invention is to provide a double-sided pressure-sensitive adhesive tape for fixing a flexible printed circuit board superior in adhesive power after bonding under low pressure and also in repelling resistance after processing in high-temperature steps.

### Solution to Problem

After intensive studies, the inventors have found that it is possible to obtain a double-sided pressure-sensitive adhesive tape for fixing a flexible printed circuit board superior in adhesive power after bonding under low pressure and also in repelling resistance after processing in high-temperature steps, by controlling the 180° peel adhesion of the adhesive tape, as determined as it is bonded under pressure (under low pressure) by one reciprocation of a 10-g roller, in a particular range, and the terminal separation distance (terminal separation distance after reflow) of the adhesive tape, as determined when it is bonded in the state where repulsive force is generated after heat treatment in the reflow step, in a particular range. The present invention was made based on these findings.

Specifically, the present invention provides a double-sided pressure-sensitive adhesive tape for fixing a flexible printed circuit board, having a 180° peel adhesion, as determined by bonding the adhesive tape onto a stainless steel plate under pressure by one reciprocation of a 10-g roller, leaving it still for 5 minutes and measuring it at a tensile speed of 300 mm/minute, of 6.5 N/20 mm or more and a terminal separation distance after reflow described below of 2.5 mm or less.

The terminal separation distance after reflow is the height of the terminal of a test sample separated from the surface of a polyimide plate surface, when a test sample having a double-sided pressure-sensitive adhesive tape carrying an aluminum plate having a thickness of 0.5 mm, a width of 10 mm, and a length of 90 mm bonded to one adhesive face thereof, is heated under the following heat treatment condition in reflow step, the test sample is then bent in the arc shape in the lengthwise direction of the test sample along a cylinder having a diameter of 30 mm with the aluminum plate facing inward, and the other adhesive face of the double-sided pressure-sensitive adhesive tape is bonded under pressure to the polyimide plate by a roll laminator under the condition of 23° C. and 0.3 in/minute and then left, as it is, under the condition of 23° C. and 50% RH for 24 hours and heated additionally at 70° C. for 2 hours. The heat treatment conditions in the reflow step are as follows:

### [Heat Treatment Condition in Reflow Step]

(1) The surface temperature of the test sample reaches 175±10° C., in the period of 130 to 180 seconds after supply of the test sample to the reflow step,
(2) The surface temperature of the test sample reaches 230±10° C., in the period of 200 to 250 seconds after supply of the test sample to the reflow step,
(3) The surface temperature of the test sample reaches 255±10° C., in the period of 260 to 300 seconds after supply of the test sample to the reflow step, and
(4) The reflow step is completed within 370 seconds after supply of the test sample to the reflow step.

The double-sided pressure-sensitive adhesive tape for fixing a flexible printed circuit board is preferably an adhesive tape having at least one pressure-sensitive adhesive layer made from a pressure-sensitive adhesive composition containing at least one phenolic hydroxyl group-containing tackifier resin, wherein the phenolic hydroxyl value of the phenolic hydroxyl group-containing tackifier resin is 1 to 50 mg-KOH/g.

The phenolic hydroxyl group-containing tackifier resin in the double-sided pressure-sensitive adhesive tape for fixing a flexible printed circuit board is preferably at least one tackifier resin selected from the group consisting of terpene phenol tackifier resins, phenol-modified rosin tackifier resins, and phenol tackifier resins.

Preferably in the double-sided pressure-sensitive adhesive tape for fixing a flexible printed circuit board, the pressure-sensitive adhesive composition is a pressure-sensitive adhesive composition containing an acrylic polymer and the content of the phenolic hydroxyl group-containing tackifier resin in the pressure-sensitive adhesive composition is 10 to 50 parts by weight with respect to the acrylic polymer (100 parts by weight).

The thickness of the double-sided pressure-sensitive adhesive tape for fixing a flexible printed circuit board is preferably 20 to 110 μm.

The present invention also provides a flexible printed circuit board carrying a double-sided pressure-sensitive adhesive tape, including a flexible printed circuit board at least including an electrical insulator layer and a conductor layer formed on the electrical insulator layer in a particular circuit pattern, and the double-sided pressure-sensitive adhesive tape for fixing a flexible printed circuit board bonded to the rear face side of the flexible printed circuit board.

### Advantageous Effects of Invention

The double-sided pressure-sensitive adhesive tape for fixing a flexible printed circuit board according to the present invention is superior in adhesive power after bonding under low pressure and also in repelling resistance after processing in high-temperature steps. Thus, the double-sided pressure-sensitive adhesive tape can be bonded to a FPC sufficiently even if it is bonded under smaller force and thus, can be fixed tightly to FPCs that cannot be processed under higher pressure, such as those carrying electronic parts mounted thereon. In addition, if the double-sided pressure-sensitive adhesive tape is bonded to a region of a casing or the like (adherend) where repulsive force is generated after processing in high-temperature steps such as flow step, it is possible to prevent troubles caused, for example, by entire or terminal separation thereof from the adherend. Thus, use of the double-sided pressure-sensitive adhesive tape for fixing a flexible printed circuit board according to the present invention leads to improvement of the processability during bonding operation of FPCs, the productivity of the FPC-containing products, and the quality of the FPC-containing products.

### BRIEF DESCRIPTION OF DRAWINGS

FIG. 1 is a schematic view (side view) illustrating the method of determining the terminal separation distance after reflow of the double-sided pressure-sensitive adhesive tape for fixing a flexible printed circuit board according to the present invention.

FIG. 2 is a graph showing an example of the temperature profile (surface temperature profile of test sample) under the heat treatment condition in the reflow step, which is used in measurement of the terminal separation distance after reflow of the double-sided pressure-sensitive adhesive tape for fixing a flexible printed circuit board according to the present invention.

FIG. 3 is a schematic view (sectional view) illustrating the test plate used in evaluation of the practical property in Examples.

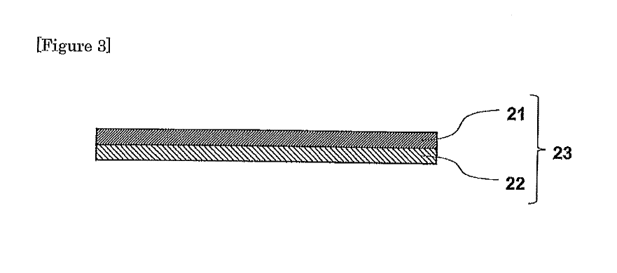

FIG. 4 is a schematic view (plan view) illustrating the state of the test plate and the polyimide plate bonded to each other, which is used in evaluation of the practical property in Examples.

### DESCRIPTION OF EMBODIMENTS

The double-sided pressure-sensitive adhesive tape for fixing a flexible printed circuit board according to the present invention (hereinafter, referred to as “the double-sided pressure-sensitive adhesive tape according to the present invention”) is a double-sided pressure-sensitive adhesive tape having adhesive faces (pressure-sensitive adhesive layer surfaces) on both faces of the tape. It should be understood that the “adhesive tapes,” as used in the present invention, include sheet-shaped materials such as “adhesive sheets.” The pressure-sensitive adhesive layer surface in the double-sided pressure-sensitive adhesive tape according to the present invention may be referred to as the “adhesive face.” As used throughout the present specification, the singular forms “a,” “an,” and “the” include plural reference unless the context clearly dictates otherwise.

The 180° peel adhesion of the double-sided pressure-sensitive adhesive tape according to the present invention, as determined by pressing the tape onto a stainless steel plate by 1 reciprocation of a 10-g roller, leaving the tape still at the state for 5 minutes and peeling the tape at a tensile speed of 300 mm/minute, (hereinafter, referred to as the “adhesive power (10 g pressurization, 5 minutes)”) is 6.5 N/20 mm or more, preferably 7.0 N/20 mm or more, more preferably 8.0 N/20 mm or more. When the adhesive power (10 g pressurization, 5 minutes) is 6.5 N/20 mm or more, the tape shows favorable adhesive power and is fixed to the adherend tightly, even if the force (pressure) used in bonding the tape to the adherend is small. The adhesive power (10 g pressurization, 5 minutes) of the double-sided pressure-sensitive adhesive tape according to the present invention on either adhesive face preferably satisfies the range above, although it is not particularly limited thereto.

When the adhesive power (10 g pressurization, 5 minutes) is controlled to be 6.5 N/20 mm or more, the tape shows favorable adhesive power, even if the pressure applied to the double-sided pressure-sensitive adhesive tape according to the present invention during bonding (under pressure) is small. Thus, the double-sided pressure-sensitive adhesive tape according to the present invention shows favorable adhesive power after bonding under low pressure. Specifically, when the double-sided pressure-sensitive adhesive tape according to the present invention is bonded to an FPC carrying electronic parts mounted thereon, it is possible advantageously to bond and fix it sufficiently without application of large force (pressure). When the adhesive power (10 g pressurization, 5 minutes) is less than 6.5 N/20 mm, it is needed to apply large force for adhesion and fixation of the double-sided pressure-sensitive adhesive tape onto a FPC carrying electronic parts mounted thereon, which may lead to troubles such as breakdown of the electronic parts during pressurization. For that reason, the double-sided pressure-sensitive adhesive tape according to the present invention can be used favorably, in particular when the double-sided pressure-sensitive adhesive tape is bonded to an FPC carrying electronic parts mounted thereon.

The adhesive power (10 g pressurization, 5 minutes) can be determined specifically, for example, by the following method:

A double-sided pressure-sensitive adhesive tape according to the present invention is cut into strips with a width of 20 mm, to give tape pieces. A PET film having a thickness of 25 μm, for example, may be bonded to the adhesive face opposite to the adhesive face for measurement of the adhesive power (10 g pressurization, 5 minutes) (measuring face) as a backing film.

The adhesive face (measuring face) of the tape piece is bonded to a test plate (stainless steel plate) under pressure by one reciprocation of a 10-g roller (width: 25 mm), to give a test sample. The pressurization speed (speed of the roller moved) during bonding under pressure may be, for example, 1 to 50 mm/second.

The 180° peel adhesion (N/20 mm) of the tape piece is determined by bonding the tape piece to a test plate under pressure and leaving it still for 5 minutes and subjecting the tape piece to a 180° peel test (in accordance with JIS 20237 (2000)) against the test plate by using a tensile tester, and used as the “adhesive power (10 g pressurization, 5 minutes).” The peeling angle was 180° and the tensile speed 300 mm/minute, and the measurement is carried out under a condition of 23° C. and 50% RH.

More specifically, it can be determined by the method described in “(1) Adhesive power after bonding under low pressure” of (Evaluation) described below.

The terminal separation distance after reflow of the double-sided pressure-sensitive adhesive tape according to the present invention is 2.5 mm or less (e.g., 0 to 2.5 mm), preferably 0 to 2.3 mm, and more preferably 0 to 2.0 mm. When the terminal separation distance after reflow is 2.5 mm or less, the adhesive tape shows favorable repelling resistance even after treatment in high-temperature steps. In the following measurement of the terminal separation distance after reflow, the terminal separation distance after reflow of the double-sided pressure-sensitive adhesive tape according to the present invention is preferably controlled in the range above, if either adhesive face is bonded to the aluminum plate, although it is not particularly limited thereto.

The terminal separation distance after reflow is the height of the terminal of a test sample separated (lifted) from the surface of a polyimide plate surface, when a test sample having a double-sided pressure-sensitive adhesive tape carrying an aluminum plate having a thickness of 0.5 mm, a width of 10 mm, and a length of 90 mm bonded to one adhesive face thereof is heated under the heat treatment condition of the following reflow step, the test sample is then bent in the arc shape in the lengthwise direction of the test sample along a cylinder having a diameter of 30 mm with the aluminum plate facing inward, and the other adhesive face of the double-sided pressure-sensitive adhesive tape is bonded under pressure to the polyimide plate by a roll laminator under the condition of 23° C. and 0.3 m/minute and then left, as it is, under the condition of 23° C. and 50% RH for 24 hours, and heated additionally at 70° C. for 2 hours. The heat treatment condition in the reflow step is as follows:

### [Heat Treatment Condition in Reflow Step]

(1) The test sample is heated to a surface temperature of 175±10° C. within 130 to 180 seconds from supply thereof to the reflow step,
(2) The test sample is heated to a surface temperature of 230±10° C. within 200 to 250 seconds from supply thereof to the reflow step,
(3) The test sample is heated to a surface temperature of 255±15° C. within 260 to 300 seconds from supply thereof to the reflow step, and
(4) The reflow step is complete within 370 seconds from supply thereof to the reflow step.

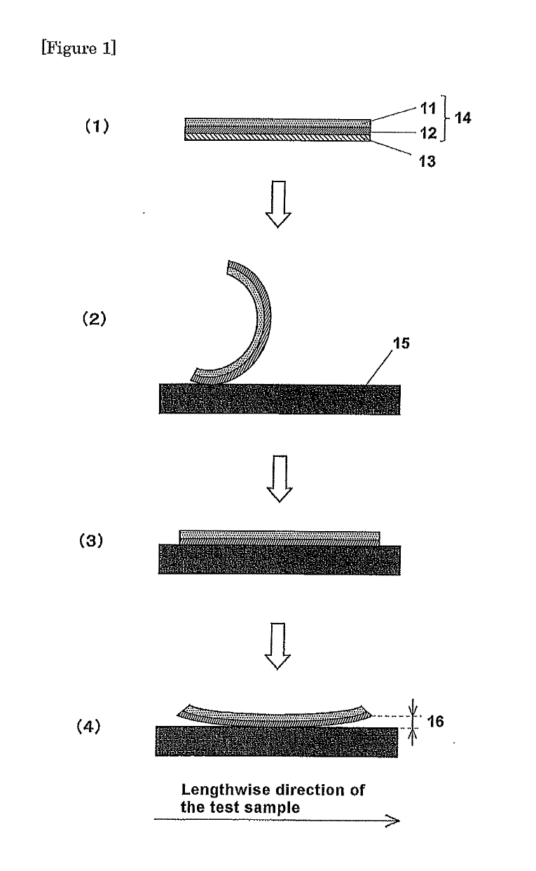

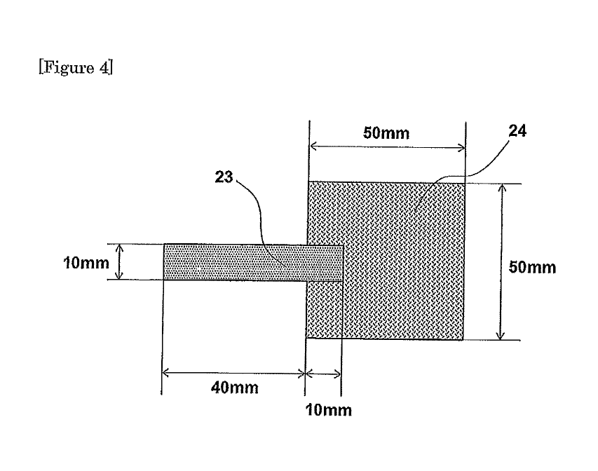

FIG. 1 is a schematic view illustrating the procedure of measuring the terminal separation distance after reflow. 14 in FIG. 1(1) represents the test sample, and the test sample 14 is prepared by bonding one adhesive face of a double-sided pressure-sensitive adhesive tape 12 to an aluminum plate 11. 13 represents a release liner (separator). After the test sample is heated under the heat treatment condition of the reflow step, it is bent in the arc shape in the lengthwise direction of the test sample along a cylinder having a diameter of 30 mm with the aluminum plate facing inward, to give a test sample in the shape shown in (2). The adhesive face of the test sample is bonded under pressure to an adherend (polyimide plate) 15 by using a roll laminator under the condition of 23° C. and 0.3 m/minute, to give a test sample in the shape shown in (3) (test sample bonded to adherend). It is stored under a condition of 23° C. and 50% RH for 24 hours and heated additionally at 70° C. for 2 hours, and the height of the terminal of the test sample separated from the adherend (the distance represented by 16 in FIG. 4)) is determined and used as the “terminal separation distance after reflow.”

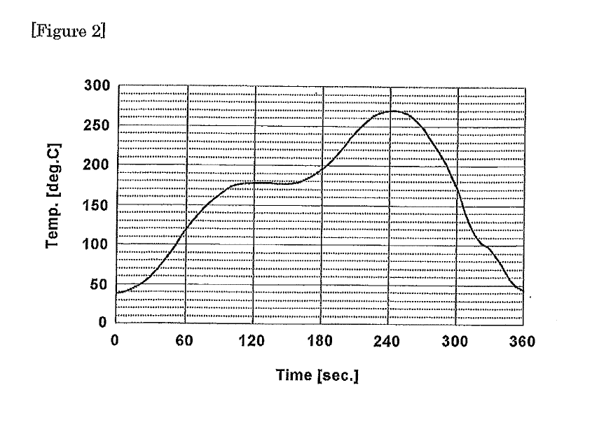

The reflow step (reflow soldering step) is not particularly limited, if it is a reflow step satisfying the requirement of the heat treatment condition, but it is, for example, a reflow step in which the test sample has the surface temperature profile shown in FIG. 2. In FIG. 2, the ordinate shows temperature (° C.) and the abscissa shows time (sec.). FIG. 2 shows an example of the temperature profile in which the peak temperature or the maximum temperature is 270° C. In the present invention, the surface temperature of the test sample in the reflow step can be determined by fixing a thermocouple on the surface (aluminum plate-sided surface) of the test sample with an adhesive tape (polyimide film-based heat-resistant adhesive tape) and monitoring the temperature continuously with a temperature sensor.

It is possible, by controlling the terminal separation distance after reflow in the range of 2.5 mm or less, to make the adhesive tape show superior repelling resistance even after processing in high-temperature steps. Specifically, it is thus possible to reduce entire or terminal separation of the double-sided pressure-sensitive adhesive tape (pressure-sensitive adhesive layer) from an adherend and fix the adhesive tape tightly to the adherend, even when, after the FPC carrying the double-sided pressure-sensitive adhesive tape according to the present invention bonded thereto is processed in a high-temperature step such as reflow step, it is bonded in the state where repulsive force is generated, for example as it is bonded to a bent or uneven region of adherend surface. When the terminal separation distance after reflow is larger than 2.5 mm, the FPC carrying the double-sided pressure-sensitive adhesive tape is vulnerable for example to entire or terminal separation, when the FPC is processed in high-temperature steps such as reflow step and then bonded to an adherend in the state where repulsive force is generated.

The double-sided pressure-sensitive adhesive tape according to the present invention may be a so-called base material-less double-sided pressure-sensitive adhesive tape having no base material (base material layer) or a base material-containing double-sided pressure-sensitive adhesive tape. The base material-less double-sided pressure-sensitive adhesive tape is, for example, a double-sided pressure-sensitive adhesive tape only having a pressure-sensitive adhesive layer. Alternatively, the base material-containing double-sided pressure-sensitive adhesive tape is, for example, a double-sided pressure-sensitive adhesive tape having pressure-sensitive adhesive layers on or above both faces of the base material. In particular, base material-containing double-sided pressure-sensitive adhesive tapes are preferable, from the viewpoint of punching efficiency. The “base material (base material layer)” does not include a release liner (separator) that is separated before use (bonding) of the adhesive tape.

### [Pressure-Sensitive Adhesive Layer]

The kind of the adhesive used for the pressure-sensitive adhesive layer constituting the double-sided pressure-sensitive adhesive tape according to the present invention is not particularly limited, and known adhesives including acrylic adhesive, rubber adhesive, vinyl alkylether adhesive, silicone adhesive, polyester adhesive, polyamine adhesive, urethane adhesive, fluorine adhesive, epoxy adhesive may be used. These adhesives may be used alone or in combination of two or more. The adhesive may be an adhesive in any types, and, for example, emulsion-type adhesives, solvent-type (solution-type) adhesives, active energy ray-curing adhesives, heat-fusing adhesives (hot-melt adhesive) and others are favorably used.

The adhesive for preparation of the pressure-sensitive adhesive layer is preferably an acrylic adhesive among them, from the viewpoint of freedom in designing. Specifically, the pressure-sensitive adhesive layer constituting the double-sided pressure-sensitive adhesive tape according to the present invention is preferably an acrylic pressure-sensitive adhesive layer. The acrylic pressure-sensitive adhesive layer is preferably a pressure-sensitive adhesive layer (acrylic pressure-sensitive adhesive layer) prepared from a pressure-sensitive adhesive composition containing an acrylic polymer as the essential component (acrylic pressure-sensitive adhesive composition). The content of the acrylic polymer in the pressure-sensitive adhesive layer (acrylic pressure-sensitive adhesive layer) (100 wt %) is not particularly limited, but preferably 65 wt % or more (e.g., 65 to 90 wt %), more preferably 68 to 87 wt %.

The acrylic polymer is preferably an acrylic polymer constituted from an alkyl (meth)acrylate having a straight-chain (linear) or branched alkyl group as the essential monomer component. The monomer components constituting the acrylic polymer may contain additionally polar group-containing monomers, polyfunctional monomers, and other copolymerizable monomers as copolymerization monomer components. Use of these copolymerization monomer components leads, for example, to improvement of the adhesive power to adherents, and also of the cohesive power of the pressure-sensitive adhesive layer. The term “(meth)acryl” means “acryl” and/or “methacryl” (one or both of “acryl” and “methacryl”), and the same will apply to similar terms.

The straight-chain or branched alkyl group-containing alkyl (meth)acrylates (hereinafter, referred to simply as “alkyl (meth)acrylates”) are, for example, alkyl (meth)acrylate esters with an alkyl group having a carbon number of 1 to 20, including methyl (meth)acrylate, ethyl (meth)acrylate, propyl (meth)acrylate, isopropyl (meth)acrylate, n-butyl (meth)acrylate, isobutyl (meth)acrylate, s-butyl (meth)acrylate, t-butyl (meth)acrylate, pentyl (meth)acrylate, isopentyl (meth)acrylate, hexyl (meth)acrylate, heptyl (meth)acrylate, octyl (meth)acrylate, 2-ethylhexyl (meth)acrylate, isooctyl (meth)acrylate, nonyl (meth)acrylate, isononyl (meth)acrylate, decyl (meth)acrylate, isodecyl (meth)acrylate, undecyl (meth)acrylate, dodecyl (meth)acrylate, tridecyl (meth)acrylate, tetradecyl (meth)acrylate, pentadecyl (meth)acrylate, hexadecyl (meth)acrylate, heptadecyl (meth)acrylate, octadecyl (meth)acrylate, nonadecyl (meth)acrylate, eicosyl (meth)acrylate and others. The alkyl (meth)acrylates may be used alone or in combination of two or more. In particular, alkyl (meth)acrylates with an alkyl group having a carbon number of 2 to 10 are preferable, and 2-ethylhexyl acrylate (2EHA) and n-butyl acrylate (BA) are more preferable.

The content of the alkyl (meth)acrylates is not particularly limited, but preferably 50 to 99 wt %, more preferably 80 to 98 wt %, and still more preferably 85 to 98 wt %, with respect to the total amount (100 wt %) of the monomer components constituting the acrylic polymer. It becomes easier to provide properties favorable as the acrylic polymer (such as tackiness) by controlling the content to 60 wt % or more.

Examples of the polar group-containing monomers include carboxyl group-containing monomers such as (meth)acrylic acid, itaconic acid, maleic acid, fumaric acid, crotonic acid, and isocrotonic acid (including acid anhydride group-containing monomers such as maleic anhydride and itaconic anhydride); hydroxyl group-containing monomers such as hydroxyalkyl (meth)acrylates (for example, 2-hydroxyethyl (meth)acrylate, 3-hydroxypropyl (meth)acrylate, 4-hydroxybutyl (methacrylate, and 6-hydroxyhexyl (methacrylate), vinyl alcohol, and allyl alcohol; amide group-containing monomers such as (meth)acrylamide, N,N-dimethyl (meth)acrylamide, N-methylol (meth)acrylamide, N-methoxymethyl (meth)acrylamide, N-butoxymethyl (meth) acrylamide, and N-hydroxyethyl acrylamide; amino-group-containing monomers such as aminoethyl (methacrylate, dimethylaminoethyl (methacrylate, and t-butylaminoethyl (methacrylate; glycidyl group-containing monomers such as glycidyl (methacrylate and methylglycidyl (meth)acrylate; cyano group-containing monomers such as acrylonitrile and methacrylonitrile; heterocyclic ring-containing vinyl monomers such as N-vinyl-2-pyrrolidone, (meth)acryloylmorpholine, N-vinylpiperidone, N-vinylpiperazine, N-vinylpyrrole, and N-vinylimidazole; alkoxyalkyl (methacrylate monomers such as methoxyethyl (methacrylate and ethoxyethyl (meth)acrylate; sulfonic acid group-containing monomers such as sodium vinylsulfonate; phosphate group-containing monomers such as 2-hydroxyethyl acryloyl phosphate; imide group-containing monomers such as cyclohexylmaleimide and isopropylmaleimide; isocyanate group-containing monomers such as 2-methacryloyloxyethyl isocyanate, and the like. These polar group-containing monomers may be used alone or in combination of two or more. In particular, the polar group-containing monomer is preferably a carboxyl group-containing monomer, more preferably acrylic acid (AA).

The content of the polar group-containing monomers is not particularly limited, but preferably 1 to 50 wt %, more preferably 2 to 20 wt %, and still more preferably 2 to 15 wt %, with respect to the total amount (100 wt %) of the monomer components constituting the acrylic polymer. A polar group-containing monomer content of 1 wt % or more prevents excessive decrease of cohesive power and improvement of adhesive power. Alternatively, a polar group-containing monomer content of less than 50 wt % prevents excessive hardening of the pressure-sensitive adhesive layer and improvement of adhesive power.

Examples of the copolymerizable monomers other than the polar group-containing monomers include alicyclic hydrocarbon group-containing (meth)acrylates such as cyclopentyl (meth)acrylate, cyclohexyl (meth)acrylate and isobornyl (meth)acrylate; aryl (meth)acrylates such as phenyl (meth)acrylate; vinyl esters such as vinyl acetate and vinyl propionate; aromatic vinyl compounds such as styrene and vinyltoluene; olefins or dimes such as ethylene, butadiene, isoprene, and isobutylene; vinylethers such as vinyl alkyl ethers; vinyl chloride and the like.

The acrylic polymers can be prepared by polymerization of the monomer components by a known or common polymerization method. Polymerization methods for the acrylic polymers include, for example, solution polymerization method, emulsion polymerization method, bulky polymerization method, polymerization method by active energy ray irradiation (active energy ray polymerization method) and the like. In particular, among them, solution polymerization method and active energy ray polymerization method are preferable, from the viewpoints of transparency, water resistance, cost and others, and solution polymerization method is more preferable.

Various general solvents may be used in the solution polymerization. The solvents are, for example, organic solvents including esters such as ethyl acetate and n-butyl acetate; aromatic hydrocarbons such as toluene and benzene; aliphatic hydrocarbons such as n-hexane and n-heptane; alicyclic hydrocarbons such as cyclohexane and methylcyclohexane; and ketones such as methylethylketone and methylisobutylketone. The solvents may be used alone or in combination of two or more.

The polymerization initiator used in polymerization for the acrylic polymer is not particularly limited and can be used, as selected properly from known or common polymerization initiators. Typical favorable examples of the polymerization initiators are oil-soluble polymerization initiators including azo polymerization initiators such as 2,2′-azobisisobutylonitrile, 2,2′-azobis(4-methoxy-2,4-dimethylvaleronitrile), 2,2′-azobis(2,4-dimethylvaleronitrile), 2,2′-azobis(2-methylbutylonitrile), 1,1′ azobis(cyclohexane-1-carbonitrile), 2,2′-azobis(2,4,4-trimethylpentane), and dimethyl-2,2′-azobis(2-methylpropionate); peroxide polymerization initiators such as benzoyl peroxide, t-butyl hydroperoxide, di-t-butyl peroxide, t-butyl peroxybenzoate, dicumyl peroxide, 1,1-bis(t-butylperoxy)-3,3,5-trimethylcyclohexane, and 1,1-bis(t-butylperoxy)cyclododecane. The polymerization initiators may be used alone or in combination of two or more. The amount of the polymerization initiators used is not particularly limited, if it is in the range in which traditional polymerization initiators are used.

The glass transition temperature (Tg) of the acrylic polymer is not particularly limited, but preferably −70 to −30° C., more preferably −65 to −35° C. A glass transition temperature of −70° C. or higher leads to improvement of heat resistance. Alternatively, a glass transition temperature of −30° C. or lower leads to improvement of adhesive power after bonding under low pressure.

The glass transition temperature (Tg) of the acrylic polymer is the glass transition temperature (theoretical value) represented by the following formula:

1/Tg=W₁/Tg₁+W₂/Tg₂+ . . . +Wₙ/Tgₙ

In the formula, Tg represents the glass transition temperature of the acrylic polymer (unit: K), Tgᵢ represents the glass transition temperature of the homopolymer prepared from monomer i (unit: K), Wᵢ represents the weight fraction of the monomer i in all monomer components (i=1, 2, . . . , n). The formula is a formula when the acrylic polymer is prepared from n kinds of monomer components: i.e., monomers 1 to n.

The glass transition temperature of the acrylic polymer can be controlled, for example, by adjustment of the kinds and contents of the monomers constituting the acrylic polymer.

The weight-average molecular weight of the acrylic polymer is not particularly limited, but preferably 400,000 to 1,500,000, more preferably 450,000 to 1,400,000, and still more preferably 500,000 to 1,300,000. When the weight-average molecular weight of acrylic polymer is 400,000 or more, the pressure-sensitive adhesive layer shows improved cohesive power. Alternatively when it is 1,500,000 or less, the pressure-sensitive adhesive composition shows improved coatability.

The weight-average molecular weight of the acrylic polymer can be controlled by adjustment of the kinds and amounts of the polymerization initiators, the temperature and period of polymerization, the monomer concentration, the monomer dropwise addition rate and others,

The pressure-sensitive adhesive composition for preparation of the pressure-sensitive adhesive layer constituting the double-sided pressure-sensitive adhesive tape according to the present invention preferably contains, in addition to the acrylic polymer, phenolic hydroxyl group-containing tackifier resins (tackifiers). Specifically, the double-sided pressure-sensitive adhesive tape according to the present invention is preferably an adhesive tape having at least one pressure-sensitive adhesive layer prepared from a pressure-sensitive adhesive composition containing at least one phenolic hydroxyl group-containing tackifier resin. Use of a phenolic hydroxyl group-containing tackifier resin leads to well balanced expression of the adhesive power after bonding under low pressure and the repelling resistance after processing in high-temperature steps. The “phenolic hydroxyl group” means a hydroxyl group directly bonded to a carbon atom constituting an aromatic ring.

Examples of the phenolic hydroxyl group-containing tackifier resins include terpene phenol tackifier resins, phenol-modified rosin tackifier resins, phenol tackifier resins and the like. The phenolic hydroxyl group-containing tackifier resins may be used alone or in combination of two or more. In particular, at least one tackifier resin selected from the group consisting of terpene phenol tackifier resins, phenol-modified rosin tackifier resins, and phenol tackifier resins is preferable, and phenol-modified rosin tackifier resins are particularly preferable, from the viewpoints of the balance between the repelling resistance after reflow and the adhesive power after bonding under low pressure.

The terpene phenol tackifier resins are, for example, phenol-modified terpene resins (terpene phenol resins) that are produced by phenol-modification of various terpene resins (α-pinene polymers, β-pinene polymers, dipentene polymers and others).

The phenol-modified rosin tackifier resins are, for example, phenol-modified rosin resins (rosin-modified phenol resins) that are produced by phenol-modification of various rosins by adding phenol to various rosins (unmodified rosins, modified rosins, or various rosin derivatives) in the presence of an acid catalyst and thermally polymerizing the resulting rosins.

The phenol tackifier resins include, for example, condensates of formaldehyde with various phenols [e.g., phenol, resorcin, and alkylphenols (particularly, p-alkylphenols) such as cresols (m-cresol, p-cresol), xylenols (3,5-xylenol, etc.), p-isopropylphenol, p-t-butylphenol, p-amylphenol, p-octylphenol, p-nonylphenol, and p-dodecylphenol), (specifically, alkylphenol resins, phenol formaldehyde resins, xylene formaldehyde resins, etc.); resols prepared by addition reaction between the phenols and formaldehyde in the presence of an alkali catalyst; novolaks prepared by condensation reaction between the phenols and formaldehyde in the presence of an acid catalyst, and the like. The number of carbons of the alkyl group in the alkylphenols is not particularly limited, and can be selected favorably, for example, from the range of 1 to 18.

The phenolic hydroxyl value of the phenolic hydroxyl group-containing tackifier resin is not particularly limited, but preferably, for example, 1 to 50 mg-KOH/g, more preferably 1 to 40 mg-KOH/g, still more preferably 1 to 35 mg-KOH/g. A phenolic hydroxyl value of 1 mg-KOH/g or more leads to improvement of the repelling resistance after processing in high-temperature steps. Alternatively, a phenolic hydroxyl value of 50 mg-KOH/g or less leads to improvement of the adhesive power after bonding under low pressure.

The phenolic hydroxyl value, which is the amount of the phenolic hydroxyl groups contained in 1 g of the phenolic hydroxyl group-containing tackifier resin, is a value, expressed as the amount (mg) of potassium hydroxide needed for neutralization of acetic acid that is bonded to the phenolic hydroxyl groups when the phenolic hydroxyl groups are acetylated. Thus, the phenolic hydroxyl value is an indicator of the amount of phenolic hydroxyl groups present in the phenolic hydroxyl group-containing tackifier resin. The phenolic hydroxyl value can be determined in accordance with JIS K0070. Specifically, it can be determined, for example, by the following [Method for determination of phenolic hydroxyl value].

### [Method for Determination of Phenolic Hydroxyl Value]

### <Reagents>

Acetylation reagent: thoroughly agitated solution of 25 g of acetic anhydride in pyridine in a total volume of 100 mL

Titration reagent: 0.5 mol/L potassium hydroxide ethanol solution

Other reagents: toluene, pyridine, ethanol, and distilled water

### <Operation>

(1) Approximately 2 g of the sample (phenolic hydroxyl group-containing tackifies resin) is weighed accurately and placed in a flat-bottomed flask; 5 mL of the acetylation reagent and 10 mL of pyridine are added thereto; and an air condenser tube is connected to the flask.
(2) The solution is heated at 100° C. for 70 minutes and then cooled gradually; 35 mL of toluene is added as solvent from the top of the air condenser tube; and after agitation, 1 mL of distilled water is added and the solution agitated for decomposition of acetic anhydride. The solution is heated additionally for 10 minutes and cooled gradually for complete decomposition.
(3) After the air condenser tube is washed with ethanol and removed, 50 mL of pyridine is added as solvent and the mixture is agitated.
(4) 25 mL of 0.5 mol/L of potassium hydroxide ethanol solution is added by using a whole pipette (volumetric pipette).
(5) The resulting solution is analyzed by potentiometric titration using 0.5 mol/L potassium hydroxide ethanol solution. The phenolic hydroxyl value is calculated in accordance with the following Formula:

$$Phenolic hydroxyl value ( mg \text{-} KOH \text{/} g ) = \frac{( B - C ) \times f \times 28.05}{S} + D \qquad [ Formula 1 ]$$

In the formula, B represents the amount (mL) of 0.5 mol/L potassium hydroxide ethanol solution used in blank test; C represents is the amount (mL) of 0.5 mol/L potassium hydroxide ethanol solution used in titration; f represents the factor of 0.5 mol/L potassium hydroxide ethanol solution; S represents the sampling amount (g) of the sample; D represents the acid value of the sample; and the value 28.05 is ½ of the molecular weight of potassium hydroxide 56.11.

The content of the phenolic hydroxyl group-containing tackifier resin in the pressure-sensitive adhesive composition for preparation of the pressure-sensitive adhesive layer constituting the double-sided pressure-sensitive adhesive tape according to the present invention is not particularly limited, but preferably, for example, 10 to 50 parts by weight, more preferably 13 to 48 parts by weight, and more preferably 15 to 45 parts by weight, with respect to 100 parts by weight of the acrylic polymer. A content of 10 parts by weight or more leads to improvement of the repelling resistance after processing in high-temperature steps. Alternatively, a content of 50 parts by weight or less leads to improvement of the adhesive power at low temperature.

The method of controlling the phenolic hydroxyl value of the phenolic hydroxyl group-containing tackifier resin in the pressure-sensitive adhesive composition in the range above is, for example, to use a tackifier resin having a phenolic hydroxyl value of 1 to 50 mg-KOH/g. Examples of the tackifier resins having a phenolic hydroxyl value of 1 to 50 mg-KOH/g for use include commercial products such as “TAMANOL 803L” (trade name, manufactured by ARAKAWA CHEMICAL INDUSTRIES, Ltd., phenolic hydroxyl value: 1 mg-KOH/g or more and less than 20 mg-KOH/g), “TAMANOL 901” (trade name, manufactured by ARAKAWA CHEMICAL INDUSTRIES, Ltd., phenolic hydroxyl value: 1 mg-KOH/g or more and less than 20 mg-KOH/g) and “SUMILITE RESIN PR-12603” (trade name, manufactured by SUMITOMO BAKELITE CO., LTD., phenolic hydroxyl value: 1 mg-KOH/g or more and less than 20 mg-KOH/g).

When the pressure-sensitive adhesive composition contains two or more phenolic hydroxyl group-containing tackifier resin, the rate (blending rate) of the tackifier resin having a phenolic hydroxyl value of 1 to 50 mg-KOH/g in the total amount (100 wt %) of the phenolic hydroxyl group-containing tackifier resin is not particularly limited, but preferably 30 wt % or more, more preferably 50 wt % or more, and still more preferably 70 wt % or more. It becomes easier, by adjusting the blending rate to 30 wt % or more, to control the phenolic hydroxyl value of the phenolic hydroxyl group-containing tackifier resin in the pressure-sensitive adhesive composition in the particular range described above and thus to balance both the adhesive power after bonding under low pressure and the repelling resistance after processing in high-temperature steps favorably.

When the pressure-sensitive adhesive composition for preparation of the pressure-sensitive adhesive layer in the double-sided pressure-sensitive adhesive tape according to the present invention contains the phenolic hydroxyl group-containing tackifier resin, the double-sided pressure-sensitive adhesive tape according to the present invention exhibits favorable repelling resistance after processing in high-temperature steps and favorable adhesive power after bonding under low pressure. It is probably because: when the pressure-sensitive adhesive composition contains a phenolic hydroxyl group-containing tackifier resin, the phenolic hydroxyl groups therein scavenge radical species generated by the heat in the high-temperature steps such as reflow step, thus preventing increase of the gel fraction of the pressure-sensitive adhesive layer and consequently improving the repelling resistance after processing in high-temperature steps. On the other hand, generally, when the pressure-sensitive adhesive composition contains a phenolic hydroxyl group-containing tackifier resin, the resulting pressure-sensitive adhesive layer becomes harder at normal temperature, causing a problem of decrease of the adhesive power after bonding under low pressure. To overcome such a problem, in the present invention, increase of the elastic modulus of the pressure-sensitive adhesive layer at normal temperature is suppressed and the adhesive power after bonding under low pressure is improved, as the phenolic hydroxyl value of the phenolic hydroxyl group-containing tackifier resin is controlled in 1 to 50 mg-KOH/g.

The pressure-sensitive adhesive composition for preparation of the pressure-sensitive adhesive layer constituting the double-sided pressure-sensitive adhesive tape according to the present invention preferably contains a crosslinking agent additionally. Use of the crosslinking agent is effective in crosslinking the base polymer constituting the pressure-sensitive adhesive layer (e.g., acrylic polymer) and increasing the cohesive power of the pressure-sensitive adhesive layer additionally. The crosslinking agent is not particularly limited and can be used, as it is selected properly from known or common crosslinking agents. Typical examples thereof favorably used include polyfunctional melamine compounds (melamine crosslinking agents), polyfunctional epoxy compounds (epoxy crosslinking agents), and polyfunctional isocyanate compounds (isocyanate crosslinking agents). The crosslinking agents may be used alone or in combination of two or more. In particular, isocyanate crosslinking agents and epoxy crosslinking agents are preferable, and epoxy crosslinking agents are more preferable,

Examples of the isocyanate crosslinking agents include lower aliphatic polyisocyanates such as 1,2-ethylene diisocyanate, 1,4-butylene diisocyanate, and 1,6-hexamethylene diisocyanate; alicyclic polyisocyanates such as cyclopentylene diisocyanate, cyclohexylene diisocyanate, isophorone diisocyanate, hydrogenated tolylene diisocyanates, and hydrogenated xylene diisocyanates; aromatic polyisocyanates such as 2,4-tolylene diisocyanate, 2,6-tolylene diisocyanate, 4,4′-diphenylmethane diisocyanate, and xylylene diisocyanate, and other agents for use include trimethylolpropane/tolylene diisocyanate adducts [e.g., trade name: “CORONATE L,” manufactured by NIPPON POLYURETHANE INDUSTRY CO., LTD.], trimethylolpropane/hexamethylene diisocyanate adducts [e.g., trade name: “CORONATE HL,” manufactured by NIPPON POLYURETHANE INDUSTRY CO., LTD.] and the like.

Examples of the epoxy crosslinking agents include N,N,N′,N′ tetraglycidyl-m-xylenediamine, diglycidylaniline, 1,3-bis(N,N-diglycidylaminomethyl)cyclohexane, 1,6-hexanediol diglycidyl ether, neopentylglycol diglycidyl ether, ethylene glycol diglycidyl ether, propylene glycol diglycidyl ether, polyethylene glycol diglycidyl ether, polypropylene glycol diglycidyl ether, sorbitol polyglycidyl ether, glycerol polyglycidyl ether, pentaerythritol polyglycidyl ether, polyglycerol polyglycidyl ether, sorbitan polyglycidyl ether, trimethylolpropane polyglycidyl ether, diglycidyl adipate, diglycidyl o-phthalate, triglycidyl-tris(2-hydroxyethyl)isocyanurate, resorcin diglycidyl ether, bisphenol-S-diglycidyl ether, epoxy resins having two or more epoxy groups in the molecule, and the like. Commercial products, such as “TETRAD C” (trade name, manufactured by MITSUBISHI GAS CHEMICAL COMPANY, INC.), may be used.

The content of the crosslinking agents in the pressure-sensitive adhesive composition is not particularly limited, but in the case of the acrylic pressure-sensitive adhesive layer, it is preferably, for example, 0.02 to 0.15 parts by weight, more preferably 0.025 to 0.08 parts by weight, and still more preferably 0.03 to 0.07 parts by weight, with respect to 100 parts by weight of the acrylic polymer. A crosslinking agent content of 0.02 parts by weight or more leads to improvement of the cohesive power of the pressure-sensitive adhesive layer. Alternatively a content of 0.15 parts by weight or less prevents excessive hardening of the pressure-sensitive adhesive layer at normal temperature and improves repelling resistance.

The pressure-sensitive adhesive composition preferably contains an antioxidant (age inhibitor) additionally. The presence of the antioxidant prevents thermal degradation of the pressure-sensitive adhesive layer after processing in high-temperature steps such as reflow step, thus preventing hardening and deterioration in adhesive power of the pressure-sensitive adhesive layer.

The antioxidant for use is not particularly limited and may be any known or common antioxidant, and examples thereof include phenol antioxidants such as hindered phenol antioxidants, amine antioxidants such as hindered amine antioxidants and the like. Commercial products, such as “Irganox 1010” (trade name Manufactured by Ciba Japan), may be used as the antioxidants.

The content of the antioxidants in the pressure-sensitive adhesive composition is not particularly limited, but preferably, for example, 0 to 5 parts by weight, more preferably 0.5 to 3 parts by weight, with respect to 100 parts by weight of the acrylic polymer. A content of 0.5 parts by weight or more prevents thermal degradation of the pressure-sensitive adhesive layer after processing in high-temperature steps, thus preventing hardening and deterioration in adhesive power of the pressure-sensitive adhesive layer.

In addition, the pressure-sensitive adhesive composition may contain, as needed, known additives such as crosslinking accelerators, fillers, colorants (pigments and dyes), ultraviolet absorbents, plasticizers, softeners, surfactants, and antistatic agents and also solvents (e.g., solvents for use in solution polymerization of the acrylic polymer described above).

The pressure-sensitive adhesive composition can be prepared, for example, by mixing an acrylic polymer (or acrylic polymer solution), a phenolic hydroxyl group-containing tackifier resin, a crosslinking agent, an antioxidant, a solvent, and other additives, although the preparation method is not particularly limited thereto.

The method of preparing the pressure-sensitive adhesive layer constituting the double-sided pressure-sensitive adhesive tape according to the present invention is not particularly limited, and an example thereof is a method of applying (coating) the pressure-sensitive adhesive composition on a base material or release liner and drying and/or curing the product, as needed.

Any known coating method can be used for the application (coating) in the method of preparing the pressure-sensitive adhesive layer, and conventional coaters, such as gravure roll coaters, reverse roll coaters, kiss roll coaters, dip roll coaters, bar coaters, knife coaters, spray coaters, comma coaters, and direct coaters, can be used.

The thickness of the pressure-sensitive adhesive layer constituting the double-sided pressure-sensitive adhesive tape according to the present invention is not particularly limited, but preferably, for example, 15 to 110 μm, more preferably 20 to 60 μm, and still more preferably 20 to 55 μm. A thickness of 15 μm or more leads to improvement of the adhesive power after bonding under low pressure and the repelling resistance. It also leads to easier dispersion of the stress generated by adhesion, which in turn makes the adhesive tape more resistant to separation. Alternatively, a thickness of 110 μm or less makes the adhesive tape more compatible to reduction in size and thickness of the product. When the double-sided pressure-sensitive adhesive tape according to the present invention has a base material, each of the pressure-sensitive adhesive layers formed on both faces of the base material preferably satisfies the requirement of the above range in thickness, although it may not be particularly limited to satisfy the requirement.

The gel fraction of the pressure-sensitive adhesive layer is not particularly limited, but preferably 20 to 70% (wt %), and more preferably 28 to 65%. The gel fraction can be determined as the matter insoluble in ethyl acetate, and it is specifically determined as the weight fraction (unit: wt of the insoluble matter after immersion of the pressure-sensitive adhesive layer in ethyl acetate at 23° C. for 7 days, with respect to the sample before immersion. A gel fraction of 20% or more leads to improvement of the cohesive power of the pressure-sensitive adhesive layer. Alternatively, a gel fraction of 70% or less prevents excessive hardening of the pressure-sensitive adhesive layer at normal temperature and improves the repelling resistance. When the double-sided pressure-sensitive adhesive tape according to the present invention has a base material, the gel fraction of each of the pressure-sensitive adhesive layers formed on both faces of the base material preferably satisfies the requirement of the range above, although it is not particularly limited thereto.

The gel fraction (the ratio of solvent-insoluble matter) is specifically a value determined, for example, by the following “method of determining gel fraction.”

### (Method of Determining Gel Fraction)

A Portion of the Pressure-Sensitive Adhesive Layer (Approximately 0.1 g) is collected from the double-sided pressure-sensitive adhesive tape according to the present invention and wrapped with a porous tetrafluoroethylene sheet having an average pore size of 0.2 μm (trade name; “NTF1122”, manufactured by Nitta Denko Corporation); the package is tied up with a kite string; and the weight of the package is determined then, as the weight before immersion. The weight before immersion is the sum of the weights of the pressure-sensitive adhesive layer (collected pressure-sensitive adhesive layer), the tetrafluoroethylene sheet, and the kite string. The total weight of the tetrafluoroethylene sheet and the kite string is also determined as the weight of the container bag.

The pressure-sensitive adhesive layer wrapped with the tetrafluoroethylene sheet and tied with the kite string (“sample”) is then placed in a 50 ml container filled with ethyl acetate and left there at 23° C. for 7 days. The sample (after ethyl acetate treatment) is then transferred from the container into an aluminum cup and dried at 130° C. for 2 hours in a drier for removal of ethyl acetate, and the weight of the sample is determined as the weight after immersion.

The gel fraction is calculated by the following Formula:

Gel fraction (wt %)=(A−B)/(C−B)×100

(in the Formula, A represents the sample weight after immersion, B represents the container bag weight, and C represents the sample weight before immersion.)

The gel fraction can be controlled, for example, by adjustment of the monomer composition and the weight-average molecular weight of the acrylic polymer or the amount of the crosslinking agent used (addition amount).

The storage elastic modulus at 23° C. of the pressure-sensitive adhesive layer, as determined by dynamic viscoelastic measurement, (hereinafter, referred to as “storage elastic modulus (23° C.)” or “G′ (23° C.)”), is not particularly limited, but preferably 4.0×10⁴ to 5.0×10⁶ Pa, more preferably 1.0×10⁵ to 2.0×10⁶ Pa. A storage elastic modulus (23° C.) of 4.0×10⁴ Pa or more leads to improvement of the cohesive power of the pressure-sensitive adhesive layer. Alternatively, a storage elastic modulus (23° C.) of 5.0×10⁶ Pa or less leads to improvement of the adhesive power after bonding under low pressure. When the double-sided pressure-sensitive adhesive tape according to the present invention has a base material, the storage elastic modulus (23° C.) of each of the pressure-sensitive adhesive layers formed on both faces of the base material preferably satisfies the requirement of the range above, although it is not particularly limited thereto.

The storage elastic modulus (23° C.) is determined by dynamic viscoelastic measurement. For example, it is determined by laminating multiple pieces of the pressure-sensitive adhesive layers to a thickness of approximately 1.5 mm and measuring the storage elastic modulus at a heating rate of 5° C./minute in the range of −70 to 200° C. under the condition of a frequency of 1 Hz in the shearing mode, by using “Advanced Rheometric Expansion System (ARES)” manufactured by Rheometric Scientific.

The storage elastic modulus (23° C.) can be controlled, for example, by adjustment of the composition of the polymer or the kind and amount of the tackifier added.

### [Base Material]

When the double-sided pressure-sensitive adhesive tape according to the present invention is a base material-containing double-sided pressure-sensitive adhesive tape, the base material is not particularly limited, but preferably, for example, a heat-resistant base material, and typical examples thereof for use are leaf-shaped materials including fiber base materials such as woven and nonwoven fabrics, felts, and nets; paper base materials such as various papers; metal base materials such as metal foils and metal plates; plastic base materials such as films and sheets of various resins (e.g., olefinic resins, polyester resins, polyvinyl chloride resins, vinyl acetate resins, amide resins, polyimide resins, polyether ether ketone, polyphenylene sulfide, etc.); rubber base materials such as rubber sheets; foams such as foam sheets; the laminated films thereof and the like. The base material may have a single- or multi-layer configuration.

In the present invention, the base material is preferably a fiber base material, particularly preferably a nonwoven fabric, from the viewpoints of heat resistance, anchoring efficiency of the pressure-sensitive adhesive (pressure-sensitive adhesive layer), cost and others. Nonwoven fabrics of heat-resistant natural fiber are used favorably as the nonwoven fabrics and, in particular, nonwoven fabrics containing Manila hemp (manila hemp nonwoven fabrics) are more preferable.

The thickness of the base material is not particularly limited, but preferably, for example, 9 to 30 μm, more preferably 10 to 25 μm, and more preferably 11 to 21 μm. A thickness of 9 μm or more leads to improvement of the punching efficiency. Alternatively, a thickness of 30 μm or less leads to preservation of the adhesive power.

When the base material is a nonwoven fabric, the basis weight of the nonwoven fabric is not particularly limited, but preferably, for example, 4 to 15 g/m², and more preferably 4.5 to 10 g/m². A basis weight of 4 g/m² or more leads to improvement of strength. Alternatively, a basis weight of 15 g/m² or less makes it easier to control the thickness in the range above.

The strength of the base material is not particularly limited, but the tensile strength thereof in the longitudinal direction (MD, or in the machine direction) is preferably, for example, 2 N/16 mm or more, and more preferably 5 N/15 mm or more.

The surface of the base material may be, as needed for improvement in adhesiveness to the pressure-sensitive adhesive layer, subjected to any known or common surface treatment, for example to oxidation by a chemical or physical method such as chromate treatment, ozone exposure, flame exposure, high-pressure electrical shock exposure, or ionizing radiation treatment and also for example to coating treatment with an undercoating agent.

The double-sided pressure-sensitive adhesive tape according to the present invention may have other layers (e.g., intermediate layer, undercoat layer, etc.), in addition to the pressure-sensitive adhesive layer and the base material, in the range that does not impair the advantageous effects of the present invention.

The thickness of the double-sided pressure-sensitive adhesive tape according to the present invention (thickness from one adhesive face to the other adhesive face) is not particularly limited, but preferably, for example, 20 to 110 μm, and more preferably 40 to 60 μm. A thickness of 20 μm or more leads to improvement of the adhesive power. Alternatively, a thickness of 110 μm or less makes the adhesive tape more compatible to reduction in size and thickness of the product.

The method of producing the double-sided pressure-sensitive adhesive tape according to the present invention is not particularly limited and may be any known or common method but, when the adhesive tape has no base material, it can be produced, for example, by forming a pressure-sensitive adhesive layer on a release liner. Alternatively, when the double-sided pressure-sensitive adhesive tape according to the present invention has a base material, for example, the pressure-sensitive adhesive layer may be formed directly on the surface of the base material (direct coating method), or may be formed on the base material indirectly by forming a pressure-sensitive adhesive layer on a release liner and transferring (bonding) it onto a base material (transfer method).

The surface of the pressure-sensitive adhesive layer (adhesive face) of the double-sided pressure-sensitive adhesive tape according to the present invention may be protected with a release liner (separator) until it is used. Each of the adhesive faces of the double-sided pressure-sensitive adhesive tape may be protected with one release liner, or both faces thereof may be protected with a single release liner that has release surfaces on both faces, as the adhesive tape is wound in a roll shape. The release liner, which is used as the protective material for the pressure-sensitive adhesive layer, is removed before adhesion thereof to the adherend. The release liner may not be necessarily formed. In particular, the double-sided pressure-sensitive adhesive tape according to the present invention preferably has a release liner on each of the adhesive faces, from the viewpoint of processability before pressurization. In other words, the double-sided pressure-sensitive adhesive tape according to the present invention is preferably a double-separator-type double-sided pressure-sensitive adhesive tape.

Examples of the release liners for use include, but are not particularly limited to, release liners having a release coating layer, specifically plastic films and papers that are surface-treated with a release coating agent (release agent) such as a silicone-, long-chain alkyl- or fluorine-release coating agent or molybdenum sulfide; low-adhesiveness base materials of a fluorochemical polymer such as polytetrafluoroethylene, polychlorotrifluoroethylene, polyvinyl fluoride, polyvinylidene fluoride, a tetrafluoroethylene-hexafluoropropylene copolymer, and a chlorofluoroethylene-vinylidene fluoride copolymer; low-adhesiveness base materials of a non-polar polymer such as an olefinic resin (e.g., polyethylene, polypropylene, or the like), and the like. In particular, release liners having a release coating layer treated with a silicone release agent (silicone release liners) are preferable from the viewpoints of cost and regulation of peeling strength (release force).

Examples of the silicone release agents include, but are not particularly limited to, thermosetting silicone release agents, ionizing radiation-hardening silicone release agents and the like. In particular, thermosetting silicone release agents are preferable for reduction of the silicone migration amount described below and improvement of the adhesive power after bonding under low pressure. In particular, silicone release agents giving a silicone release coating layer containing a smaller amount of low-molecular weight uncrosslinked components after drying and/or hardening are desirable.

The thermosetting silicone release agent used as the silicone release agent in the release liner is not particularly limited, if it is silicone release agent that hardens under heat, but preferably a thermal-addition-reaction silicone release agent that forms a release film by crosslinking (hardening reaction) in thermal addition reaction. The thermosetting silicone release agents may be used alone or in combination of two or more.

The thermal-addition-reaction silicone release agent for use may be a thermal-addition-reaction polysiloxane release agent containing a polysiloxane polymer containing groups that are reactive to the groups containing Si—H bonds in the molecule and a polysiloxane polymer having hydrogen atoms bound to silicon atoms in the molecule. The “Si—H bond” means the “bond between a silicon atom (Si) and a hydrogen atom (H).”

The group that is reactive to the groups containing Si—H bonds in the molecule in the polysiloxane polymer containing groups that are reactive to the groups containing Si—H bonds is, for example, an alkenyl group such as vinyl group, hexenyl group, or the like. The polysiloxane polymer containing groups that are reactive to the groups containing Si—H bonds in the molecule preferably has two or more of the alkenyl groups in the molecule. Alternatively, the polysiloxane polymer having hydrogen atoms bound to silicon atoms in the molecule preferably contains two or more hydrogen atoms bound to silicon atoms. Thus, the thermal-addition-reaction silicone release agent is preferably a silicone release agent containing a polysiloxane polymer having two or more alkenyl groups in the molecule and a polysiloxane polymer having two or more hydrogen atoms bound to silicon atoms in the molecule.

In the polysiloxane polymer having two or more alkenyl groups in the molecule, the alkenyl groups are normally bound directly to the silicon atoms (e.g., terminal silicon atoms, silicon atoms in main chain) in the polysiloxane polymer forming the main chain or the skeleton. Thus, the polysiloxane polymer having two or more alkenyl groups in the molecule is preferably a polysiloxane polymer having two or more alkenyl groups directly bound to silicon atoms in the molecule. Examples of the polysiloxane polymer forming the main chain or the skeleton include polyalkylalkylsiloxane polymers such as polydimethylsiloxane polymers, polydiethylsiloxane polymers, and polymethylethylsiloxane polymers; polyalkylarylsiloxane polymers; copolymers of multiple silicon atom-containing monomer components [for example, poly(dimethylsiloxane-diethylsiloxane)] and the like, and in particular, polydimethylsiloxane polymers are preferable.

On the other hand, the silicon atoms to which hydrogen atoms are bonded in the polysiloxane polymer having two or more hydrogen atoms bonded to silicon atoms in the molecule may be silicon atoms in the main chain or those in side chains. The polysiloxane polymer having two or more hydrogen atoms bound to silicon atoms in the molecule is preferably a polydimethylhydrogensiloxane polymer [such as poly (dimethylailoxane-methylsiloxane)]. The polysiloxane polymer having two or more hydrogen atoms bound to silicon atoms in the molecule has a function as a crosslinking agent in the thermal-addition-reaction silicone release agent.

The amount of the polysiloxane polymer having two or more hydrogen atoms bound to silicon atoms in the molecule used is not particularly limited, and can be selected properly in accordance with the desired hardening efficiency, peeling strength and others of the film. Specifically, the polysiloxane polymer having two or more hydrogen atoms bound to silicon atoms in the molecule is preferably used, for sufficient hardening of the film, as the molar number (hereinafter, referred to as “molar number (X)”) of the silicon atoms to which hydrogen atoms are bonded (i.e., silicon atoms in Si—H bond) in the polysiloxane polymer having two or more hydrogen atoms bound to silicon atoms in the molecule and the molar number (hereinafter, referred to as “molar number (Y)”) of the alkenyl groups in the polysiloxane polymer having two or more alkenyl groups in the molecule satisfy the following formula: Molar number (X)≧Molar number (Y). These polymers are normally used at a molar number (X)/molar number (Y) ratio of 1.0 to 2.0 (preferably 1.2 to 1.6).

A catalyst may be used in the hardening reaction of the polysiloxane polymer having two or more alkenyl groups in the molecule with a polysiloxane polymer having two or more hydrogen atoms bound to silicon atoms in the molecule (crosslinking agent). The catalyst is not particularly limited, but preferably, a platinum catalyst (e.g., platinum fine particles, or a platinum compound such as chloroplatinic acid or the derivative thereof). The amount of the catalyst used is not particularly limited, but preferably 0.1 to 1000 ppm, more preferably 1 to 100 ppm, with respect to the polysiloxane polymer having two or more alkenyl groups in the molecule.

The thermal-addition-reaction silicone release agent can be prepared by mixing the constituent components (e.g., a polysiloxane polymer having two or more alkenyl groups in the molecule, a polysiloxane polymer having two or more hydrogen atoms bound to silicon atoms in the molecule and, as needed, catalysts and various additives) and, as needed, an organic solvent.

The thermal-addition-reaction silicone release agent can be used, as the polymer components such as polysiloxane polymer are dissolved in organic solvent. The thermal-addition-reaction silicone release agent may contain, as needed, known or common additives [e.g., fillers, antistatic agents, antioxidants, ultraviolet absorbents, plasticizers, colorants (dyes, pigments, etc.)].

The liner base material for the release liner (base material for release liner) in the double-sided pressure-sensitive adhesive tape according to the present invention is not particularly limited, and various base materials including plastic base materials, paper base materials, fiber base materials and others may be used. The liner base material may have a single- or multi-layer configuration. The plastic base material can be selected properly from various plastic base materials, and examples thereof include polyolefin base materials (polyethylene base materials, polypropylene base materials, etc.), polyester base materials (polyethylene terephthalate base materials, polyethylene naphthalate base materials, polybutylene terephthalate base materials, etc.), polyamide base materials (so-called, “nylon” base material, etc.), cellulosic base materials (so-called, “cellophane” base materials) and the like. The paper base material can be selected properly from various paper base materials, and examples thereof include Japanese papers, Western papers, woodfree papers, glassine papers, Kraft papers, Clupak papers, crape papers, clay coated papers, synthetic papers, papers coated with an acrylic resin or polyvinylalcohol resin on the surface (hereinafter, referred to as “resin-coated papers”) and the like. In particular, paper base materials are preferable, and glassine papers and resin-coated papers are particularly preferable.

The liner base material may be subjected, as needed, to various surface treatments such as corona discharge and embossing.

The thickness of the liner base material is not particularly limited, and may be selected properly for example depending on applications, but it is generally preferably 2 to 200 μm, more preferably 25 to 150 μm.

The thickness of the release liner is not particularly limited, but preferably 70 to 130 μm, more preferably 80 to 120 μm.

The release liner in the double-sided pressure-sensitive adhesive tape according to the present invention can be prepared, for example, by forming the release coating layer finished with a silicone release agent on the surface of a liner base material, although the preparation method is not particularly limited thereto. Specifically, it is for example a method of forming a release coating layer by coating a thermosetting silicone release agent described above (in particular, a thermal-addition-reaction silicone release agent), in an amount giving a particular thickness after drying and/or hardening, on the surface of a liner base material and drying and/or hardening the film under heat.

The method of heating method for drying and/or hardening the film after coating the thermosetting silicone release agent is not particularly limited, and used, as it is properly selected from known heating methods (e.g., heating methods by electric heater, electromagnetic waves such as infrared rays, and others).

It is important to coat the release agent such as the thermosetting silicone release agent on the liner base material in a suitable coating amount. Excessively small coating amount of the release agent often causes practical problems, as the peeling strength (force needed for peeling) becomes too large, while excessively large coating amount may lead to increase of the silicone migration amount described below and thus to deterioration of the adhesive power and also of the adhesive power after bonding under low pressure. It may also lead to increase of cost, making the process less economical, and also to elongation of the hardening period, which leads to decrease in productivity. The amount of the release agent favorably coated (as solid matter) may vary, for example, depending on the kind of the pressure-sensitive adhesive composition used, the kind of the liner base material, and the kind of the silicone release agent, but it is preferably, for example, 0.001 to 10 g/m², more preferably 0.05 to 5 g/m².

When the double-sided pressure-sensitive adhesive tape according to the present invention has a release liner on at least one adhesive face, the amount of silicone depositing on the adhesive face after separation of the release liner (hereinafter, referred to as “silicone migration amount”) is preferably 20 Kcps or less, and more preferably 5 Kcps or less. It is possible to prevent deterioration in adhesive power and also of adhesive power after bonding under low pressure, by adjusting the silicone migration amount to 20 Kcps or less. A silicone migration amount of 20 Kcps or less means that the amount of silicone present on the adhesive face of the double-sided pressure-sensitive adhesive tape is limited, and in such a case, generation of silicone-derived siloxane gases and contamination of the adherend are suppressed. Accordingly, it also reduces corrosion and contact failure of the electronic parts in products prepared by fixing a FPC on them by using the double-sided adhesive sheet according to the present invention (e.g., hard disk drives, etc.)

The silicone migration amount, which is the amount of silicone that migrates from the release liner surface (release coating layer surface) to the pressure-sensitive adhesive layer surface, is determined on the adhesive faces on both faces of the double-sided pressure-sensitive adhesive tape. The silicone migration amount can be determined, specifically according to the following method:

### [Method of Determining Silicone Migration Amount]

A double-sided pressure-sensitive adhesive tape according to the present invention (double-sided pressure-sensitive adhesive tape having a release liner) is cut into pieces with the sized of width 50 mm×length 50 mm, to give test samples. The release liner is then removed from the test sample and the amount of silicone compounds present on the exposed adhesive face is determined by using a XRF apparatus (“Rigaku ZSX 100e,” manufactured by Rigaku Corporation).

The silicone migration amount can be controlled, for example, by adjustment of the kind of the silicone release agent used.

The double-sided pressure-sensitive adhesive tape according to the present invention is a double-sided pressure-sensitive adhesive tape for fixing a flexible printed circuit board (double-sided pressure-sensitive adhesive tape for a flexible printed circuit board) for use in the application of fixing a FPC to an adherend such as casing. The double-sided pressure-sensitive adhesive tape according to the present invention suppresses terminal or entire separation of the pressure-sensitive adhesive layer (adhesive tape), even if it is bonded after processing in high-temperature steps such as reflow step in the state where repulsive force is generated. The double-sided pressure-sensitive adhesive tape according to the present invention, which shows sufficient adhesive power even when bonded under low pressure, can be used favorably, especially in the cases where large force cannot be applied for adhesion, specifically in the cases where it is bonded to a FPC carrying electronic parts and others mounted.

The FPC fixed by the double-sided pressure-sensitive adhesive tape according to the present invention includes an electrical insulator layer (hereinafter, referred to as “base insulation layer”), a conductor layer formed in a particular circuit pattern on the base insulation layer (hereinafter, referred to as “conductor layer”), and, as needed, an electrical insulator layer for covering (hereinafter, referred to as “cover insulation layer”) formed on the conductor layer, although the configuration thereof is not particularly limited thereto. It may have a multi-layered structure in which multiple circuit boards are laminated.

The base insulation layer is an electrical insulator layer formed with an electrically insulating material. The electrically insulating material for preparation of the base insulation layer is not particularly limited, and can be used, as it is selected from electrically insulating materials used in known FPCs. Typical favorable examples of the electrically insulating materials are plastic materials including polyimide resins, acrylic resins, polyether nitrile resins, polyether sulfone resins, polyester resins (polyethylene terephthalate resin, polyethylene naphthalate resin, etc.), polyvinyl chloride resins, polyphenylene sulfide resins, polyether ether ketone resins, polyamide resins (so-called “aramide resins,” etc.), polyarylate resins, polycarbonate resins, liquid crystal polymers and the like. These electrically insulating materials can be used alone or in combination of two or more. In particular, polyimide resins are preferable. The base insulation layer may have a single-layer structure or multi-layer structure. The surface of the base insulation layer may be subjected to various surface treatments (e.g., corona discharge treatment, plasma treatment, surface-roughening treatment, hydrolysis treatment, etc.) The thickness of the base insulation layer is not particularly limited, but preferably 3 to 100 μm, more preferably 5 to 50 μm, and more preferably 10 to 30 μm.

The conductor layer is a conductor layer made of a conductor. The conductor layer is formed on the base insulation layer in a particular circuit pattern. The conductor for preparation of such a conductor layer is not particularly limited and can be used, as it is selected properly from the conductors used in known FPCs. Typical examples of the conductors include metal materials such as copper, nickel, gold, chromium, various alloys (e.g., solders), and platinum, conductive plastic materials and the like. The conductors can be used alone or in combination of two or more. Among the materials above, metal materials (in particular, copper) are preferable. The conductor layer may have a single-layer structure or multi-layer structure. The surface of the conductor layer may be subjected to various surface treatments. The thickness of the conductor layer is not particularly limited, but preferably 1 to 50 μm, more preferably 2 to 30 μm, and more preferably 3 to 20 μm.

The method of forming the conductor layer is not particularly limited, and can be selected properly from known methods (e.g., known patterning methods such as subtractive method, additive method, and semi-additive method). For example, when the conductor layer is formed directly on the surface of the base insulation layer, the conductor layer can be formed by depositing a conductor on the base insulation layer by plating or vapor deposition in a particular circuit pattern, by using an electroless plating, electrolytic plating, vacuum deposition, sputtering or other method.

The cover insulation layer is an electrical insulator layer for covering (electrical insulator layer for protection) that is formed with an electrically insulating material and covers the conductor layer. The cover insulation layer is formed, as needed, and thus may not be formed. The electrically insulating material used in forming the cover insulation layer is not particularly limited, and can be used, as it is selected properly from the electrically insulating materials used in known FPCs, similarly to the case of the base insulation layer. Typical examples of the electrically insulating materials used in forming the cover insulation layer include electrically insulating materials exemplified as the electrically insulating materials used for forming the base insulation layer, and the plastic materials (in particular, polyimide resin) are preferable, similarly to the case of the base insulation layer. The electrically insulating materials for forming the cover insulation layer may be used alone or in combination of two or more. The cover insulation layer may have a single-layer structure or multi-layer structure. The surface of the cover insulation layer may be subjected to various surface treatments (e.g., corona discharge treatment, plasma treatment, surface-roughening treatment, hydrolysis treatment, etc.) The thickness of the cover insulation layer is not particularly limited, but preferably 3 to 100 μm, more preferably 5 to 50 μm, and more preferably 10 to 30 μm.

The method of forming the cover insulation layer is not particularly limited, and can be selected properly from known preparation methods (e.g., method of coating and drying a liquid or melt containing an electrically insulating material, method of laminating a film or sheet of an electrically insulating material that is suitable in shape to the conductor layer, etc.).

It is possible to obtain an FPC having (carrying) a double-sided pressure-sensitive adhesive tape, by bonding a double-sided pressure-sensitive adhesive tape according to the present invention to the rear face side (surface of opposite to the conductor layer of the electrical insulator layer) of the FPC (FPC at least having an electrical insulator layer and a conductor layer formed on the electrical insulator layer in a particular circuit pattern), although the production method is not particularly limited thereto. It is possible to fix a FPC on an adherend such as casing or reinforcing plate via the double-sided pressure-sensitive adhesive tape according to the present invention, by bonding the FPC carrying the double-sided pressure-sensitive adhesive tape to the adherend.

Examples of the adherends to which the FPC is fixed via the double-sided pressure-sensitive adhesive tape according to the present invention include, but are not particularly limited to, cellphone casings, motors, bases, substrates, covers and the like. In addition, hard disk drives, cellphones, motors and others are produced, as a FPC is bonded and fixed to the adherend via the double-sided adhesive sheet according to the present invention.

The adherend to which the FPC is fixed is, for example, a supporting plate such as reinforcing plate. Such a reinforcing plate is formed normally on the face opposite to the conductor layer of the base insulation layer (rear face). The reinforcing plate material used in preparing the reinforcing plate is not particularly limited, and may be used, as it is selected properly from reinforcing plate materials for preparation of known reinforcing plates. The reinforcing plate material may be conductive or nonconductive. Typical examples of the reinforcing plate materials include metal materials such as stainless steel, aluminum, copper, iron, gold, silver, nickel, titanium and chromium; plastic materials such as polyimide resins, acrylic resins, polyether ether ketone resins, polyether sulfone resins, polyester resins (polyethylene terephthalate resin, polyethylene naphthalate resin, etc.), polyvinyl chloride resins, polyphenylene sulfide resins, polyether ether ketone resins, polyamide resins (so-called “aramide resin,” etc.), polyarylate resins, polycarbonate resins, epoxy resins, glass epoxy resins, and liquid crystal polymers; inorganic materials such as alumina, zirconia, soda-lime glass, quartz glass, and carbon; and the like. The reinforcing plate materials may be used alone or in combination of two or more. In particular, among them, metal materials such as stainless steel and aluminum, plastic materials such as polyimide resin are preferable, and in particular, stainless steel and aluminum are used more favorably. Thus, the reinforcing plate is preferably formed with a metal foil or metal plate (e.g., stainless steel foil or stainless steel plate, aluminum foil or aluminum plate) or a plastic film (e.g., polyimide resin film). The reinforcing plate may have a single-layer structure or multi-layer structure. The surface of the reinforcing plate may be subjected to various surface treatments. The thickness of the reinforcing plate is not particularly limited, but preferably, for example, 50 to 2000 μm, and more preferably 100 to 1000 μm.

### EXAMPLES

Hereinafter, the present invention will be described more in detail with reference to Examples, but it should be understood that the present invention is not restricted by these Examples.

### Preparation Example of Release Liner 1

A coating solution containing a thermosetting silicone release agent [major agent 1 (trade name: “AST-10-XL,” manufactured by ARAKAWA CHEMICAL INDUSTRIES, LTD.): 25 parts by weight, major agent 2 (trade name: “AST-6-XL,” manufactured by ARAKAWA CHEMICAL INDUSTRIES, LTD.): 25 parts by weight, hardening agent 1 (trade name: “AST-10-ATA,” manufactured by ARAKAWA CHEMICAL INDUSTRIES, LTD.): 25 parts by weight, and hardening agent 2 (trade name: “AST-6-CATA,” manufactured by ARAKAWA CHEMICAL INDUSTRIES, LTD.): 25 parts by weight] was prepared. The coating solution was applied on the surface of a glassine paper (trade name: “NSGP-RT100,” manufactured by Oji Specialty Paper Co., Ltd.) in a coating amount (as solid content) of 2.5 g/m², to give a release liner (hereinafter, referred to as “release liner 1”).

### Preparation Example of Release Liner 2

A release coating layer (coating amount (as solid content): 2.5 g/m²) composed of a silicone release agent (which was prepared by mixing a cationically polymerizable UV-hardening silicone release agent (trade name: “X-62-7658,” manufactured by Shin-Etsu Chemical Co., Ltd.): 100 parts by weight and an ultraviolet cleavage-type initiator (trade name: “CAT-7605,” manufactured by Shin-Etsu Chemical Co., Ltd.): 1 part by weight and dissolving the mixture in heptane to a solid content concentration of 1.0 wt %) was formed on the surface of a glassine paper (trade name: “NSGP-RT100,” manufactured by Oji Specialty Paper Co., Ltd.), to give a release liner (hereinafter, referred to as “release liner 2”). The release coating layer was formed by coating, drying, and ultraviolet hardening of the silicone release agent.

### Example 1

90 parts by weight of 2-ethylhexyl acrylate (2EHA) and 10 parts by weight of acrylic acid (AA) as monomer components, 0.6 part by weight of benzoyl peroxide as polymerization initiator, and 210 parts by weight of ethyl acetate as polymerization solvent were placed in a separable flask and agitated for 1 hour while introducing nitrogen gas stream. After removal of oxygen in the polymerization system in this way, the mixture was heated to 63° C., allowed to react for 10 hours, and added with ethyl acetate, to give an acrylic polymer solution at a solid content concentration of 30 wt % (Tg of the acrylic polymer in the acrylic polymer solution: −60° C.).

As shown in Table 1, 0.05 part by weight of an epoxy crosslinking agent (trade name: “TETRAD C,” manufactured by MITSUBISHI GAS CHEMICAL COMPANY, INC.) as a crosslinking agent, 20 parts by weight of a phenol-modified rosin resin (trade name: “TAMANOL 803L,” manufactured by ARAKAWA CHEMICAL INDUSTRIES, LTD., phenolic hydroxyl value: 1 mg-KOH/g or more and less than 20 mg-KOH/g) as a tackifies resin, and 1 part by weight of “Irganox1010,” (manufactured by Ciba Japan) as an antioxidant were added to 100 parts by weight of an acrylic polymer in the acrylic polymer solution, to give a pressure-sensitive adhesive composition (acrylic pressure-sensitive adhesive composition).

The pressure-sensitive adhesive composition above was coated on the surface of the release liner 1 and dried at 130° C. for 5 minutes, to give a pressure-sensitive layer having a thickness of 20 μm. The pressure-sensitive adhesive layer was then bonded to both faces of a manila hemp nonwoven fabric (thickness: 18 μm), to give a double-sided pressure-sensitive adhesive tape having a total thickness (thickness from one surface of the pressure-sensitive adhesive layer to the other) of 50 μm.

### Example 2

A double-sided pressure-sensitive adhesive tape having a total thickness of 50 μm was prepared in a manner similar to Example 1, except that 20 parts by weight of a phenol-modified rosin resin (trade name: “TAMANOL 901,” manufactured by ARAKAWA CHEMICAL INDUSTRIES, LTD., phenolic hydroxyl value: 1 mg-KOH/g or more and less than 20 mg-KOH/0 (with respect to 100 parts by weight of the acrylic polymer) was used as the tackifier resin.

### Example 3

A double-sided pressure-sensitive adhesive tape having a total thickness of 60 μm was prepared in a manner similar to Example 1, except that 20 parts by weight of a phenol-modified rosin resin (trade name: “SUMILITE RESIN PR-12603,” manufactured by SUMITOMO BAKELITE CO., LTD., phenolic hydroxyl value: 1 mg-KOH/g or more and less than 20 mg-KOH/g) (with respect to 100 parts by weight of the acrylic polymer) was used as the tackifier resin.

### Example 4

100 parts by weight of n-butyl acrylate (BA) and 5 parts by weight of acrylic acid (AA) as monomer components, 0.2 part by weight of benzoyl peroxide as polymerization initiator, and 240 parts by weight of toluene as polymerization solvent were placed in a separable flask and agitated for 2 hour while introducing nitrogen gas stream. After removal of oxygen in the polymerization system in this way, the mixture was heated to 62° C., allowed to react for 7 hours, to give an acrylic polymer solution at a solid content concentration of 30 wt % (Tg of the acrylic polymer in the acrylic polymer solution: −49° C.).

As shown in Table 1, 0.05 part by weight of an epoxy crosslinking agent (trade name: “TETRAD C,” manufactured by MITSUBISHI GAS CHEMICAL COMPANY, INC.) as a crosslinking agent, 30 parts by weight of a phenol-modified rosin resin (trade name: “TAMANOL 803L,” manufactured by ARAKAWA CHEMICAL INDUSTRIES, LTD., phenolic hydroxyl value: 1 mg-KOH/g or more and less than 20 mg-KOH/g) and 10 parts by weight of a terpene phenol resin (trade name: “YS Polyster S145,” manufactured by YASUHARA CHEMICAL Co., Ltd., phenolic hydroxyl value: 77 mg-KOH/g) as tackifies resins, and 1 part by weight of “Irganox1010,” (manufactured by Ciba Japan) as an antioxidant were added to 100 parts by weight of an acrylic polymer in the acrylic polymer solution, to give a pressure-sensitive adhesive composition (acrylic pressure-sensitive adhesive composition).

The pressure-sensitive adhesive composition above was coated on the surface of the release liner 1 and dried at 130° C. for 5 minutes, to give a pressure-sensitive adhesive layer having a thickness of 20 μm. The pressure-sensitive adhesive layer was then bonded to both faces of a manila hemp nonwoven fabric (thickness: 18 pin), to give a double-sided pressure-sensitive adhesive tape having a total thickness (thickness from one surface of the pressure-sensitive adhesive layer to the other) of 50 μm.

### Comparative Example 1

A double-sided pressure-sensitive adhesive tape having a total thickness of 50 μm was obtained in a manner similar to Example 1, except that 20 parts by weight of a terpene phenol resin (trade name: “YS Polyster S145,” manufactured by YASUHARA CHEMICAL Co., Ltd., phenolic hydroxyl value: 77 mg-KOH/g) (with respect to 100 parts by weight of the acrylic polymer) was used as the tackifier resin and the release liner 2 was used as the release liner,

### Comparative Example 2

A double-sided pressure-sensitive adhesive tape having a total thickness of 50 μm was obtained in a manner similar to Example 1, except that 20 parts by weight of an alkylphenol resin (trade name: “TAMANOL 100S,” manufactured by ARAKAWA CHEMICAL INDUSTRIES, LTD., phenolic hydroxyl value: 239 mg-KOH/g) (with respect to 100 parts by weight of the acrylic polymer) was used as the tackifier resin and the release liner 2 was used as the release liner.

### Comparative Example 3

A double-sided pressure-sensitive adhesive tape having a total thickness of 50 μm was obtained in a manner similar to Example 1, except that no tackifier resin was used and release liner 2 was used as the release liner.

### (Evaluation)

The Double-Sided Pressure-Sensitive Adhesive Tapes Obtained in Examples and Comparative Examples were measured or evaluated by the following measurement or evaluation methods. The results of the measurement or evaluation are summarized in Table 1.

(1) Adhesive Power after Bonding Under Low Pressure

One release liner was separated from each of the double-sided pressure-sensitive adhesive tapes obtained in Examples and Comparative Examples, a PET film (thickness: 25 μm) was bonded (for backing) to the adhesive face exposed, and the composite was cut into strips of 20 mm width×150 mm length, to give tape pieces.

The other release liner was removed from the tape piece, and the adhesive face exposed was pressed (pressurization speed: approximately 25 mm/second) onto a test plate (stainless steel plate) by one reciprocation of a 10-g rubber roller (width: approximately 25 mm), to give a test sample.

After storage for 5 minutes from pressurization of the tape piece onto the test plate, the test sample was subjected to a 180° peel test of tape piece by using a tensile tester (in accordance with JIS Z0237 (2000)), to determine the 180° peel adhesion. The 180° peel test was performed at a peeling angle of 180° and a tensile speed of 300 min/minute. The 180° peel adhesion was measured under the condition of 23° C. and 50% RH.

The test number (n) was 3 and the average was calculated, and the results are summarized in the column of “adhesive power after bonding under low pressure” in Table 1.

(2) Terminal Separation Distance after Reflow

One release liner was removed (separated) from each of the double-sided pressure-sensitive adhesive tapes obtained in Examples and Comparative Examples (size: 10 mm width×90 mm length), and the adhesive face exposed was bonded to an aluminum, plate (10 mm width×90 mm length, thickness: 0.5 mm), to give a test sample.

The test sample was placed still at room temperature for one hour and then, heated in the reflow step under the condition of a peak temperature of 270° C. in an infrared oven (IR-heating oven).

After heating in the reflow step, the test sample was bent into the arc shape in the longitudinal direction (lengthwise direction) along a round bar having a diameter (φ) of 30 mm with the aluminum plate facing inward. The other release liner of the test sample was then removed for exposure of the adhesive face, and one terminal of the test sample in the lengthwise direction (adhesive face side) was bonded temporarily to an adherend (polyimide plate) and the test sample was then firmly pressed by using a roll laminator (pressurization condition: 23° C., 0.3 m/minute). The test sample was left still under ambient atmosphere (23° C., 50% RH) for 24 hours and additionally heated at 70° C. for 2 hours and the height (mm) of the test sample terminal separated (lifted) from the adherend surface was determined and the average of the separation heights at both terminal of the test sample was calculated as the “terminal separation distance after reflow.”

### (Reflow Step)

The reflow device or apparatus used was an infrared heating oven [the maximum or peak temperature was set to 270° C.; conveyor-type far-infrared/hot air-heating apparatus (manufactured by NORITAKE CO., LIMITED.)]. The surface temperature of the test sample was monitored continuously with a temperature sensor [KEYENCE NR-250, manufactured by Keyence CORPORATION)], as the thermocouple was bonded to the test sample surface with an adhesive tape (polyimide film heat-resistant adhesive tape). FIG. 2 shows an example of the temperature profile [ordinate: temperature (° C.), abscissa: time (sec)] under the heat treatment condition in the reflow step. The period of the reflow step was 360 seconds.

### (3) Practical Property

A test sample prepared by bonding one adhesive face of the double-sided pressure-sensitive adhesive tape to a polyimide film (Kapton 500V) having a width of 10 mm and a length of 50 mm was bonded to the end face (terminal) of a polyimide plate (width: 50 mm, length: 50 mm) at a bonding area of 10 mm×10 mm square and pressed by one reciprocation of a 40-g roller. The resulting composite was left still under the condition of 23° C. and 50% RH for 24 hours and additionally heated at 70° C. for 24 hours, and examined visually whether the test sample was separated (lifted) from the polyimide plate surface or not. The practical property was considered to be favorable (A) when the test sample was not separated from the polyimide plate surface, and it was considered unfavorable (3) when the test sample was separated from the polyimide plate surface.

The test above is a test (model test) for evaluation of the practical property of whether it is possible to fix a FPC to an adherend such as reinforcing plate or casing by using the double-sided pressure-sensitive adhesive tape.

TABLE 1

| | | | | | | | | Compar- | Compar- | Compar- |
|---|---|---|---|---|---|---|---|---|---|---|
| | | | | | | | | ative | ative | ative |
| | | | Example 1 | Example 2 | Example 3 | Example 4 | | Example 1 | Example 2 | Example 3 |
| Ingredients | Polymer (part by weight) | | 100 | 100 | 100 | 100 | | 100 | 100 | 100 |
| (composition | TETRAD C | | 0.05 | 0.05 | 0.05 | 0.05 | | 0.05 | 0.05 | 0.05 |
| of pressure- | (part by weight) | | | | | | | | | |
| sensitive | Added | Product name | TAMANOL | TAMANOL | PR- | TAMANOL | YS Polyster | YS Polyster | TAMANOL | — |
| adhesive | resin | | 803L | 901 | 1260S | 803L | S145 | S145 | 100S | |
| composition) | | Kind | Phenol- | Phenol- | Phenol- | Phenol- | Terpene | Terpene | Alkylphenol | — |
| | | | modified | modified | modified | modified | phenol | phenol | resin | |
| | | | rosin | rosin | rosin | rosin | resin | resin | | |
| | | | resin | resin | resin | resin | | | | |
| | | Phenolic | <20 | <20 | <20 | <20 | 77 | 77 | 239 | — |
| | | hydroxyl value | | | | | | | | |
| | | (mgKOH/g) | | | | | | | | |
| | | (part by | 20 | 20 | 20 | 30 | 10 | 20 | 20 | — |
| | | weight) | | | | | | | | |

| | | | | | | | |
|---|---|---|---|---|---|---|---|
| Irganox 1010 | 1 | 1 | 1 | 1 | 1 | 1 | 1 |
| (part by weight) | | | | | | | |

| Tape configuration | | With base materiel (50 mm) | | | | | | |
|---|---|---|---|---|---|---|---|---|
| Adhesive power after | 5 minutes after | 8.5 | 7.1 | 7.1 | 10.5 | 5.3 | 1.7 | 6.8 |
| bonding under | 10 g | | | | | | | |
| low pressure | pressurization | | | | | | | |
| | (N/20 mm) | | | | | | | |

| | | | | | | | |
|---|---|---|---|---|---|---|---|
| Terminal separation distance (mm) | 1.1 | 1.6 | 1.5 | 1.2 | 1.1 | 1.0 | 2.8 |
| Practical property | A | A | A | A | B | B | B |

As obvious from the results in Table 1, since the double-sided pressure-sensitive adhesive tapes obtained in Examples had larger adhesive power after bonding under low pressure and smaller terminal separation distance after reflow and had favorable repelling resistance after processing in high-temperature steps, they are superior in Practical property. In contrast, the double-sided pressure-sensitive adhesive tapes when they have excessively low adhesive power after bonding under low pressure (Comparative Examples 1 and 2) or when they have unfavorable repelling resistance after processing in high-temperature steps (Comparative Example 3), were unfavorable in the practical property.

Abbreviations used in Table 1 are as follows:

TETRAD C: trade name: “TETRAD C,” manufactured by MITSUBISHI GAS CHEMICAL COMPANY, INC.
Irganox 1010: trade name: “Irganox1010,” manufactured by Ciba Japan
TAMANOL 803L: trade name: “TAMANOL 803L,” manufactured by ARAKAWA CHEMICAL INDUSTRIES, LTD.
TAMANOL 901: trade name: “TAMANOL 901,” manufactured by ARAKAWA CHEMICAL INDUSTRIES, LTD.
PR-12603: trade name: “SUMILITE RESIN PR-12603,” manufactured by SUMITOMO BAKELITE CO., LTD.
YS Polyster S145: trade name: “YS Polyster S145,” manufactured by YASUHARA CHEMICAL Co., Ltd.
TAMANOL 100S: trade name: “TAMANOL 100S,” manufactured by ARAKAWA CHEMICAL INDUSTRIES, LTD.

### REFERENCE SIGNS LIST

11 Aluminum plate
12 Double-sided pressure-sensitive adhesive tape
18 Release liner
14 Test sample
15 Adherend (polyimide plate)
16 Terminal separation distance after reflow
21 Polyimide film
22 Double-sided pressure-sensitive adhesive tape
23 Test sample
24 Polyimide plate

1. A double-sided pressure-sensitive adhesive tape for fixing a flexible printed circuit board, having a 180° peel adhesion, as determined by bonding the adhesive tape onto a stainless steel plate under pressure by one reciprocation of a 10-g roller, leaving it still for 5 minutes and measuring it at a tensile speed of 300 mm/minute, of 6.5 N/20 mm or more and a terminal separation distance after reflow described below of 2.5 mm or less.
[Terminal Separation Distance after Reflow]
the height of the terminal of a test sample separated from the surface of a polyimide plate, when a test sample having a double-sided pressure-sensitive adhesive tape carrying an aluminum plate having a thickness of 0.5 mm, a width of 10 mm, and a length of 90 mm bonded to one adhesive face thereof, is heated under the following heat treatment condition in reflow step, the test sample is then bent in the arc shape in the lengthwise direction of the test sample along a cylinder having a diameter of 30 mm with the aluminum plate facing inward, and the other adhesive face of the double-sided pressure-sensitive adhesive tape is bonded under pressure to the polyimide plate by a roll laminator under the condition of 23° C. and 0.3 m/minute and then left, as it is, under the condition of 23° C. and 50% RH for 24 hours and heated additionally at 70° C. for 2 hours.
[Heat Treatment Condition in Reflow Step]
(1) the surface temperature of the test sample reaches 175±10° C., in the period of 130 to 180 seconds after supply of the test sample to the reflow step (2) the surface temperature of the test sample reaches 230±10° C., in the period of 200 to 250 seconds after supply of the test sample to the reflow step
(3) the surface temperature of the test sample reaches 255±15° C., in the period of 260 to 300 seconds after supply of the test sample to the reflow step
(4) the reflow step is completed within 370 seconds after supply of the test sample to the reflow step.

2. The double-sided pressure-sensitive adhesive tape for fixing a flexible printed circuit board according to claim 1, which is an adhesive tape having at least one pressure-sensitive adhesive layer made from a pressure-sensitive adhesive composition containing at least one phenolic hydroxyl group-containing tackifier resin, wherein the phenolic hydroxyl value of the phenolic hydroxyl group-containing tackifier resin is 1 to 50 mg-KOH/g.

3. The double-sided pressure-sensitive adhesive tape for fixing a flexible printed circuit board according to claim 2, wherein the phenolic hydroxyl group-containing tackifier resin is at least one tackifier resin selected from the group consisting of terpene phenol tackifier resins, phenol-modified rosin tackifier resins, and phenol tackifier resins.

4. The double-sided pressure-sensitive adhesive tape for fixing a flexible printed circuit board according to claim 2, wherein the pressure-sensitive adhesive composition is a pressure-sensitive adhesive composition containing an acrylic polymer and the content of the phenolic hydroxyl group-containing tackifier resin in the pressure-sensitive adhesive composition is 10 to 50 parts by weight with respect to the acrylic polymer (100 parts by weight).

5. The double-sided pressure-sensitive adhesive tape for fixing a flexible printed circuit board according to claim 1, wherein the thickness thereof is 20 to 110 μm.

6. A flexible printed circuit board carrying a double-sided pressure-sensitive adhesive tape, comprising a flexible printed circuit board at least including an electrical insulator layer and a conductor layer formed on the electrical insulator layer in a particular circuit pattern, and the double-sided pressure-sensitive adhesive tape for fixing a flexible printed circuit board according to claim 1 bonded to the rear face side of the flexible printed circuit board.

7. The double-sided pressure-sensitive adhesive tape for fixing a flexible printed circuit board according to claim 3, wherein the pressure-sensitive adhesive composition is a pressure-sensitive adhesive composition containing an acrylic polymer and the content of the phenolic hydroxyl group-containing tackifier resin in the pressure-sensitive adhesive composition is 10 to 50 parts by weight with respect to the acrylic polymer (100 parts by weight).

8. The double-sided pressure-sensitive adhesive tape for fixing a flexible printed circuit board according to claim 2, wherein the thickness thereof is 20 to 110 μm.

9. The double-sided pressure-sensitive adhesive tape for fixing a flexible printed circuit board according to claim 3, wherein the thickness thereof is 20 to 110 μm.

10. The double-sided pressure-sensitive adhesive tape for fixing a flexible printed circuit board according to claim 4, wherein the thickness thereof is 20 to 110 μm.

11. The double-sided pressure-sensitive adhesive tape for fixing a flexible printed circuit board according to claim 7, wherein the thickness thereof is 20 to 110 μm.

12. A flexible printed circuit board carrying a double-sided pressure-sensitive adhesive tape, comprising a flexible printed circuit board at least including an electrical insulator layer and a conductor layer formed on the electrical insulator layer in a particular circuit pattern, and the double-sided pressure-sensitive adhesive tape for fixing a flexible printed circuit board according to claim 2 bonded to the rear face side of the flexible printed circuit board.

13. A flexible printed circuit board carrying a double-sided pressure-sensitive adhesive tape, comprising a flexible printed circuit board at least including an electrical insulator layer and a conductor layer formed on the electrical insulator layer in a particular circuit pattern, and the double-sided pressure-sensitive adhesive tape for fixing a flexible printed circuit board according to claim 3 bonded to the rear face side of the flexible printed circuit board.

14. A flexible printed circuit board carrying a double-sided pressure-sensitive adhesive tape, comprising a flexible printed circuit board at least including an electrical insulator layer and a conductor layer formed on the electrical insulator layer in a particular circuit pattern, and the double-sided pressure-sensitive adhesive tape for fixing a flexible printed circuit board according to claim 4 bonded to the rear face side of the flexible printed circuit board.

15. A flexible printed circuit board carrying a double-sided pressure-sensitive adhesive tape, comprising a flexible printed circuit board at least including an electrical insulator layer and a conductor layer formed on the electrical insulator layer in a particular circuit pattern, and the double-sided pressure-sensitive adhesive tape for fixing a flexible printed circuit board according to claim 5 bonded to the rear face side of the flexible printed circuit board.

16. A flexible printed circuit board carrying a double-sided pressure-sensitive adhesive tape, comprising a flexible printed circuit board at least including an electrical insulator layer and a conductor layer formed on the electrical insulator layer in a particular circuit pattern, and the double-sided pressure-sensitive adhesive tape for fixing a flexible printed circuit board according to claim 7 bonded to the rear face side of the flexible printed circuit board.

17. A flexible printed circuit board carrying a double-sided pressure-sensitive adhesive tape, comprising a flexible printed circuit board at least including an electrical insulator layer and a conductor layer formed on the electrical insulator layer in a particular circuit pattern, and the double-sided pressure-sensitive adhesive tape for fixing a flexible printed circuit board according to claim 8 bonded to the rear face side of the flexible printed circuit board.

18. A flexible printed circuit board carrying a double-sided pressure-sensitive adhesive tape, comprising a flexible printed circuit board at least including an electrical insulator layer and a conductor layer formed on the electrical insulator layer in a particular circuit pattern, and the double-sided pressure-sensitive adhesive tape for fixing a flexible printed circuit board according to claim 9 bonded to the rear face side of the flexible printed circuit board.

19. A flexible printed circuit board carrying a double-sided pressure-sensitive adhesive tape, comprising a flexible printed circuit board at least including an electrical insulator layer and a conductor layer formed on the electrical insulator layer in a particular circuit pattern, and the double-sided pressure-sensitive adhesive tape for fixing a flexible printed circuit board according to claim 10 bonded to the rear face side of the flexible printed circuit board.

20. A flexible printed circuit board carrying a double-sided pressure-sensitive adhesive tape, comprising a flexible printed circuit board at least including an electrical insulator layer and a conductor layer formed on the electrical insulator layer in a particular circuit pattern, and the double-sided pressure-sensitive adhesive tape for fixing a flexible printed circuit board according to claim 11 bonded to the rear face side of the flexible printed circuit board.
